(19) United States
(12) Patent Application Publication
(10) Pub. No.: US 2010/0206234 A1
(43) Pub. Date: Aug. 19, 2010

(54) SIMPLIFIED POWDER FEEDING AND VAPORIZATION APPARATUS

(76) Inventor: MICHAEL LONG, Hilton, NY (US)

Correspondence Address: Raymond L. Owens;Patent Legal Staff, Eastman Kodak Company, 343 State Street, Rochester, NY, 14650-2201, US

(21) Appl. No.: 12/371,940

(22) Filed: Feb. 17, 2009

(51) Int. Cl. C23C 16/00

(52) U.S. Cl. 118/726

(57) ABSTRACT

An apparatus for vaporizing a particulate material, including: a metering apparatus including: a reservoir for receiving particulate material; the reservoir having an opening for discharging the particulate material into a vaporizing chamber; a rotatable wire wheel brush disposed in the reservoir; wherein the dimensions of the reservoir and the wire wheel brush are selected so that the wire wheel brush cooperates with the interior walls of the reservoir to fluidize the particulate material and wherein a metered portion of the particulate material is entrained in the tines of the wire wheel brush and subsequently forcefully released into the reservoir opening; and a flash evaporator that receives and vaporizes the metered material.

### CROSS REFERENCE TO RELATED APPLICATIONS

Reference is made to commonly assigned U.S. patent application Ser. No. 12/271,211, filed Nov. 14, 2008, by Long et al.; the disclosures of which are incorporated herein by reference.

### FIELD OF THE INVENTION

The present invention relates to metering of particulate materials, over a large range of feed rates, into a vaporization apparatus.

### BACKGROUND OF THE INVENTION

There is a need to be able to dispense small quantities of finely divided powders with high weight or volume accuracy for batch processes operating in a vacuum. There is also a need to dispense powders in a continuous stream with a high accuracy and consistency in the dispensing rate for continuous processes operating in a vacuum. For some processes, for example, the weight accuracy necessary is plus or minus 10 micrograms and the rate consistency is plus or minus 10 micrograms per second.

The electronics industry in particular has a need to meter small quantities of powdered materials to a vaporization zone for direct vapor deposition or for precursors in chemical vapor deposition (CVD). There is also a need to be able to accurately and precisely meter material amounts at much higher rates, for example 1000 micrograms per second. In many systems, it would be advantageous to be able to meter powdered materials over the range of 1 to 1000 micrograms with the same equipment. Organic light emitting diode devices (OLEDs), for instance, have a light-emitting layer that often contains a host and a dopant that are deposited in amounts differing by two to three orders of magnitude. There would be a great advantage in OLED manufacturing to be able to independently, and continuously, meter powdered organic materials to a vaporization region using a common transport design for host, co-host and dopant materials.

It is well known that precisely metering small amounts of powdered materials is difficult. There are numerous examples of systems in the pharmaceutical industry, for example, that make use additional materials as carriers and additives to facilitate the accurate dispensing of powdered materials. Carriers that have been used include inert gases, liquids, and solids. The use of any sort of additive increases the material transport complexity, for the carrier or additive needs to be added, removed, and handled separately from the actual material of interest. The use of carriers also increases the risk of contamination, which is particularly detrimental in the pharmaceutical and electronics manufacturing industries where there is a particular need to meter materials.

In U.S. Pat. No. 3,754,529, Fleischner describes an auger device for transporting powdered material that has been mixed with an inert carrier, preferably sand. The ratio of active material to sand is reported to be 1:9. Transporting a mixture that is mostly inert carrier effectively reduces the powder dispensing accuracy requirements by an order of magnitude if the mixture is homogeneous, but this method adds cost and complexity to the system and increases the potential for the introduction of contaminates into the material feed.

Commonly assigned U.S. Patent Application Publication Nos. 2006/0062918 and No. 2006/0177576 use a traditional auger design to meter powders in a vaporization device, where there is a patterned screw within a smooth barrel. FIG. 1 shows a cross-sectional view of a typical prior art auger structure 8 showing a patterned auger screw 5 within a smooth barrel 7. The terminal end of auger screw 5 can be configured to have a thread-free portion 9 having a constant circular cross-section over a small length to constrain the consolidated particulate material to form a narrow annular or tubular shape. One of the problems with using this type of auger structure with powders is varying discharge rate. The discharge rate has been observed to vary cyclically with the angular orientation of auger screw 5. The quantity of material discharged by the auger from revolution to revolution can be quite reproducible, but within a revolution it is quite variable. Another problem with auger structures is that they are prone to jamming if the powder is not free flowing or tends to pack into a consolidated mass. Their use with powders whose particle size is less than 50 microns tends to be problematic.

Additional difficulty is encountered if the powder-dispensing system is used to deliver powder to a vaporization process. Many organic materials are subject to thermal decomposition when exposed to high temperatures for extended periods of time, so vaporization systems are advantageously designed to actively cool the powder in a reservoir and the powder feeding mechanism, forcing the material to undergo a rapid temperature rise to the vaporization temperature in a short period of time as it is dispensed into the vaporization apparatus. The difficulty in maintaining adjacent hot and cold regions is that vapor from the heated powder will condense on surfaces cooler than the vapor's condensation temperature and quickly foul most powder delivery systems.

Vapor deposition systems of particular interest are those designed for manufacturing organic light emitting diode (OLED) devices. An OLED device includes a substrate, an anode, a hole-transporting layer made of an organic compound, an organic luminescent layer with suitable dopants, an organic electron-transporting layer, and a cathode. OLED devices are attractive because of their low driving voltage, high luminance, wide-angle viewing and capability for full-color flat emission displays. Tang et al. described this multilayer OLED device in their U.S. Pat. Nos. 4,769,292 and 4,885,211.

Physical vapor deposition in a vacuum environment is the principal method of depositing thin organic material films as used in small molecule OLED devices. Such methods are well known, for example Barr in U.S. Pat. No. 2,447,789 and Tanabe et al. in EP 0 982 411. The organic materials used for OLED devices are often subject to degradation when maintained at or near the desired rate-dependent vaporization temperature for extended periods of time. Exposure of sensitive organic materials to higher temperatures can cause changes in the structure of the molecules and associated changes in material properties.

To overcome the thermal sensitivity of these materials, only small quantities of organic materials have been loaded in prior art deposition sources, and they are heated as little as possible. In this manner, the material is consumed before it has reached the temperature exposure threshold to cause significant degradation. The limitations with this practice are that the available vaporization rate is very low due to the limitation on heater temperature, and the operation time of the source is very short due to the small quantity of material present in the source. In the prior art, it has been necessary to vent the deposition chamber, disassemble and clean the vapor source, refill the source, reestablish vacuum in the deposition chamber, and degas the just-introduced organic material over several hours before resuming operation. The low deposition rate and the frequent and time-consuming process associated with recharging a source has placed substantial limitations on the throughput of OLED manufacturing facilities.

A secondary consequence of heating the entire organic material charge to roughly the same temperature is that it is impractical to mix additional organic materials, such as dopants, with a host material unless the vaporization behavior and vapor pressure of the dopant is very close to that of the host material. Additionally, the standard use of separate sources creates a gradient effect in the deposited film where the material in the source closest to the advancing substrate is over-represented in the initial film immediately adjacent the substrate while the material in the last source is over represented in the final film surface. This gradient co-deposition is unavoidable in prior art sources where a different single material is vaporized from each of multiple sources directly onto a substrate. The gradient in the deposited film is especially evident when the contribution of either of the end sources is more than a few percent of the central source, such as when a co-host is used. FIG. 2 shows a cross-sectional view of such a prior-art vaporization device 10, which includes three individual sources 11, 12, and 13 for vaporizing organic material. Vapor plume 14 is preferably homogeneous in the materials from the different sources, but in fact varies in composition from side to side resulting in a non-homogeneous coating on substrate 15.

Commonly assigned U.S. Patent Application Publication Nos. 2006/0062918 and 2006/0062919 overcome many of the shortcomings of the use of separate point sources by metering materials to a flash vaporization zone. U.S. Patent Application Publication No. 2006/0062918 teaches the metering of host and dopant mixtures in a single powder transport mechanism, and using a manifold to distribute the vapor to the substrate. U.S. Patent Application Publication No. 2006/062919 discloses the ability to mix organic vapors in the manifold and deliver a mixture of materials to the substrate surface. However, none of these earlier teachings anticipates the need to have independent metering control for the host and dopant materials. The transport mechanisms are therefore unable, by virtue of design, to meter at the low rates, 1-10 micrograms/second, required for an independent dopant feed.

U.S. Patent Application Publication Nos. 2007/0084700 and 2006/0157322, U.S. Pat. Nos. 6,832,887 and 7,044,288 disclose powder feeding pumps, which move powders from an entry port to a discharge port using parallel spaced disks. The disks rotate within a housing having a volume that increases from the input port to the discharge port. These powder feeding pumps are intended for use with much larger particle size powders and are not adapted to metering powder on a milligram or microgram basis.

There continues to be a need to precisely control the metering of milligram to microgram quantities of powdered material into a vaporization apparatus.

### SUMMARY OF THE INVENTION

There is a continued need to precisely control the metering and delivery of milligram to microgram quantities of particulate material to a vaporization device.

This object is achieved by an apparatus for vaporizing a particulate material, comprising:

a. a metering apparatus including:
i. a reservoir for receiving particulate material;
ii. the reservoir having an opening for discharging the particulate material into a vaporizing chamber;
iii. a rotatable wire wheel brush disposed in the reservoir;
iv. wherein the dimensions of the reservoir and the wire wheel brush are selected so that the wire wheel brush cooperates with the interior walls of the reservoir to fluidize the particulate material and wherein a metered portion of the particulate material is entrained in the tines of the wire wheel brush and subsequently forcefully released into the reservoir opening; and

b. a flash evaporator that receives and vaporizes the metered material.

### ADVANTAGES

It is an advantage of this invention that it can provide adjustable controlled metering and vaporization of small quantities of particulate material more uniformly than many prior art devices. The particulate material transport apparatus of the present invention can accurately deliver small amounts of particulate material such as 1 microgram per second, as well as much larger amounts, such as up to 1000 micrograms per second. It is a further advantage of the present invention that it can meter particulate materials uniformly without the use of a carrier, such as an inert gas, liquid or solid. It is a further advantage of the present invention that it can maintain a steady vaporization rate with a continuously replenished charge of particulate material and with no heater temperature change required as the source material is consumed. It is a further advantage of the present invention that the particulate material is maintained at lower temperature in the material reservoir and is heated only as it is discharged into the associated vaporizing chamber. The device permits extended operation of the source with substantially higher vaporization rates than in many prior art devices and has substantially reduced risk of degrading even very temperature-sensitive organic materials. It is a further advantage of the present invention that it can be used in a vaporization system for independently controlling multiple feed rates, such as dopant and host. It is a farther advantage of this invention that it permits rapid starting and stopping of vaporization. It is a further advantage of this invention that it can deliver controlled volumes of vapor and thereby control the deposited film thickness in area deposition processes. It is a further advantage of the present invention that it can provide a vapor source in any orientation, which is frequently not possible with prior-art devices.

### BRIEF DESCRIPTION OF THE DRAWINGS

FIG. 1 shows a cross-sectional view of an auger-delivery portion of a prior-art vaporization device;

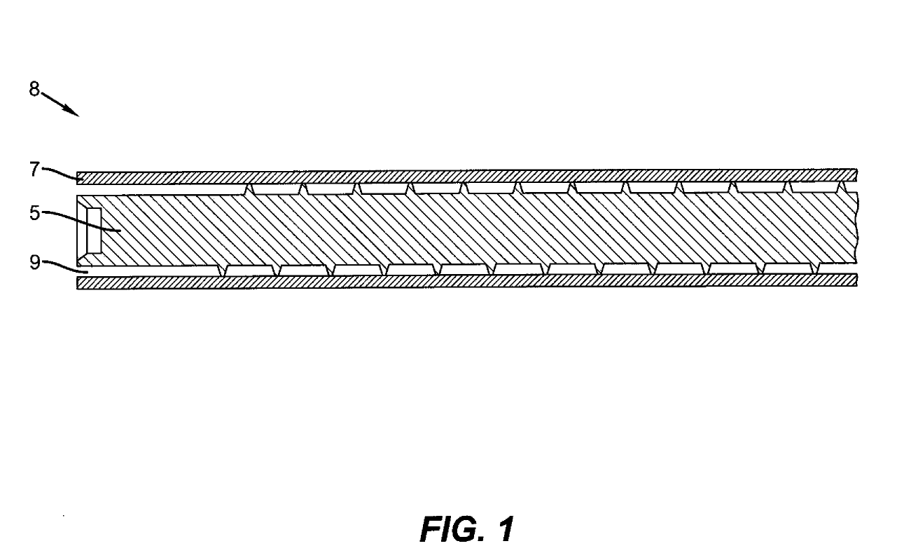

FIG. 2 shows a cross-sectional view of a portion of a different prior-art vaporization device;

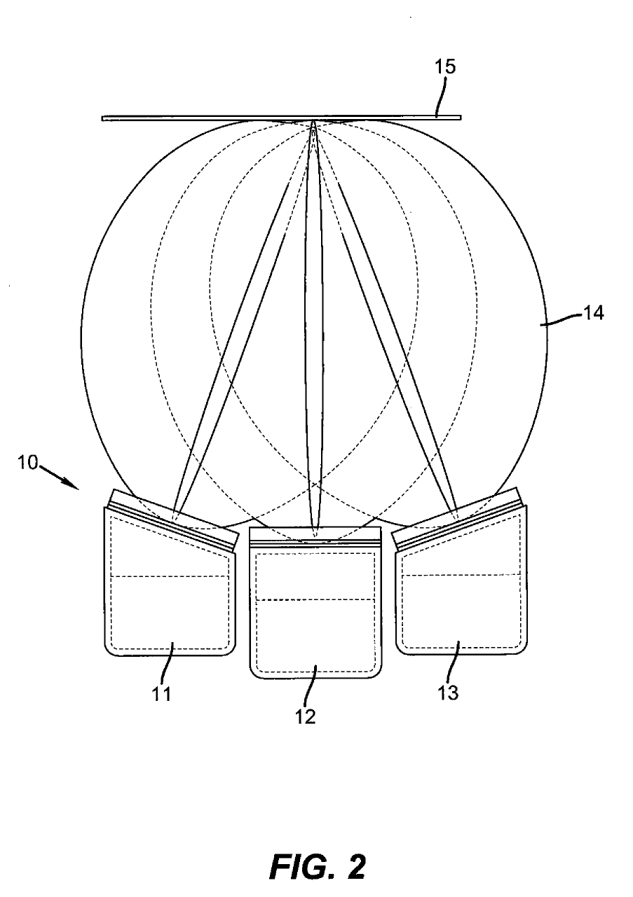

FIG. 3 shows a three-dimensional cross-sectional view of one embodiment of an apparatus according to the present invention;

FIG. 4 shows a cross-sectional view of a portion of the inventive apparatus of FIG. 3;

FIG. 5 shows a cross-sectional view of a portion of FIG. 4 in greater detail;

FIG. 6 shows a three-dimensional cross-sectional view of a portion of the inventive apparatus of FIG. 3;

FIG. 7 shows a three-dimensional view of the rotatable flash evaporator of FIG. 3 showing a magnetic coupling for driving the rotatable flash evaporator; and

FIG. 8 shows a cross-sectional view of an embodiment of the apparatus of this invention in another orientation.

### DETAILED DESCRIPTION OF THE INVENTION

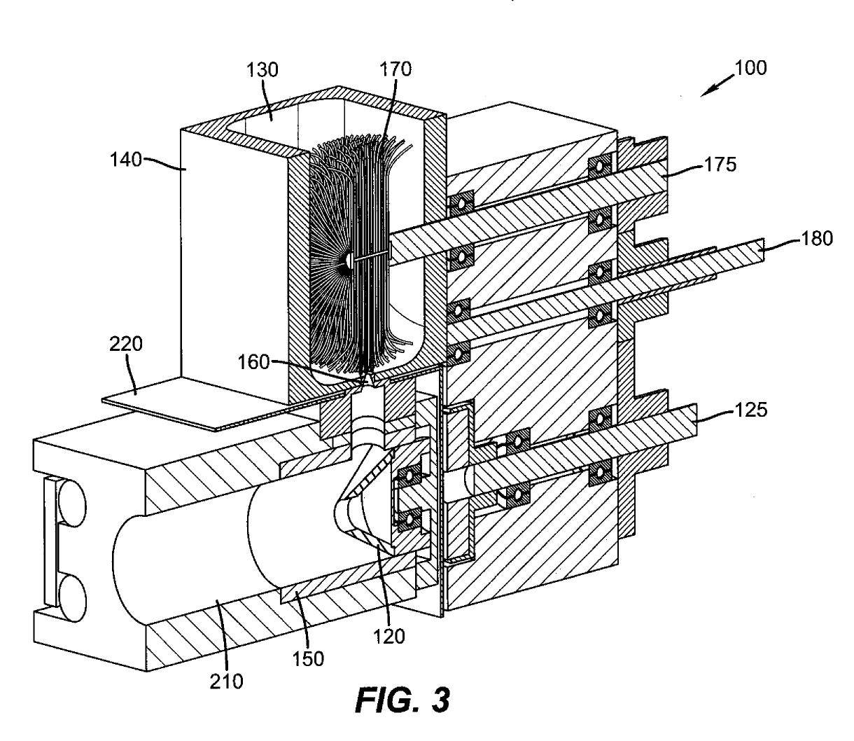

Turning now to FIG. 3, there is shown a three-dimensional cross-sectional view of one embodiment of an apparatus according to the present invention. Vaporizing apparatus 100 is an apparatus for vaporizing particulate material. Vaporizing apparatus 100 includes a metering apparatus, which includes a housing having a reservoir for receiving particulate material, an opening in the reservoir for discharging the material into a vaporizing chamber, and a rotatable wire brush wheel disposed in the reservoir. These components will be described in more detail. Reservoir 130 is in housing 140 and is for receiving particulate material. The particulate material can include a single component, or can include two or more different material components, each one having a different vaporization temperature. Although not shown, reservoir 130 can include a larger storage and feeding apparatus above it to increase the volume of particulate material that can be loaded. Such containers and feeding apparatus have been described by Long et al. in commonly assigned U.S. Pat. No. 7,288,285. Housing 140 is preferably constructed of thermally conductive material, such as aluminum, which can be actively cooled and serves to maintain the particulate material in reservoir 130 at a temperature well below its effective vaporization temperature.

Rotatable wire wheel brush 170 is disposed in reservoir 130 and is preferably constructed of thermally conductive material such as nickel or stainless steel, which can be actively cooled and helps to maintain the particulate material retained within its bristles at a temperature well below the effective vaporization temperature. Hard coatings such as titanium nitride or diamond-like carbon are advantageously applied to the interior of housing 140. Wire wheel brush 170 can be rotated by a motor (not shown) attached to shaft 175. Alternatively, a motor can be attached to shaft 180, which can then drive shafts 175 and 125, e.g. by a gear arrangement. Shaft 125 is used to rotate flash evaporator 120, which will be described below. Reservoir 130 also includes an opening at the bottom for discharging particulate material at a metered rate into vaporizing chamber 210. Vaporizing apparatus 100 also includes a rotatable flash evaporator 120 within vaporizing chamber 210. Flash evaporator 120 receives the particulate material discharged into vaporizing chamber 210 and vaporizes the metered material. Vaporizing chamber 210 can also include a cylindrical foam element 150 around a portion of its walls. Vaporizing apparatus 100 can further optionally include a pressure sensor (not shown) to measure the pressure inside vaporizing chamber 210, and which can therefore monitor the rate of material vaporization. It is also useful to have an insulator 220 between vaporizing chamber 210 and housing 140 to reduce heat transfer to the housing. Insulator 220 can include synthetic mica such as that marketed by the Cogebi Group, an insulating ceramic material, a thin gap, or simply light contact between vaporizing chamber 210 and housing 140.

The dimensions of reservoir 130 and wire wheel brush 170 are selected so that the wire wheel brush cooperates with the interior walls of the reservoir to fluidize the particulate material. A metered portion of the particulate material is entrained in the tines of the wire wheel brush and subsequently forcefully released into the reservoir opening; Wire wheel brush 170 rotates and is in contact with a portion of the wall of a particulate material reservoir 130. The brush pushes particulate material against the wall and through opening 160 in the wall of reservoir 130 to transfer particulate material from the reservoir to vaporizing chamber 210. As the brush rotates through particulate material in the reservoir, the particles are agitated or fluidized around the brush and tend to be entrained in the spaces between the tines of the brush. The tines rotate into contact with the walls of reservoir 130 and are displaced from their free position. As the brush continues to rotate, some of the tines pass over opening 160 in the wall of the reservoir, allowing those tines to spring back, at least partially, toward their rest position. The sudden displacement of these tines fluidizes the particulate material in the vicinity of opening 160, causing material particles to be forcefully released into the opening. The contact between the tines and the wall of the reservoir continually removes any condensate that can otherwise adhere there. Additionally, by deforming the tines as they rotate against the wall of the reservoir and allowing them to straighten somewhat as they pass over opening 160, causes the tines to project to some degree into the opening to further dislodge condensate and allow reliable operation even where condensate fouling would normally be problematic.

Wire wheel brush 170, in cooperation with reservoir 130, therefore acts to agitate or fluidize particulate material in the reservoir, to transport the material from the reservoir to discharge opening 160, to locally fluidize material at the discharge opening, and to dislodge condensate that collects around the opening on a continual basis.

A wire wheel brush having an outer diameter of 40 mm, composed of a multitude of 0.05 mm diameter stainless steel tines whose free length is 14 mm has proven to be effective in metering free flowing powders. Other wheel diameters will also be effective. It is important that the tines be sufficiently compliant to allow that they be deformed when contacting the interior walls of the reservoir and can spring back when passing over the discharge opening.

The feed rate uniformity is improved when the particulate material in proximity to the discharge opening is fluidized by agitation, e.g. by rotation of the rotatable wire wheel brush and the localized spring action of the tines passing over the discharge opening. Wire wheel brush 170 is well adapted to feeding mixed-component particle materials as it imparts very little energy to the bulk of the particulate material in the reservoir and is therefore not likely to cause particle separation by size or density.

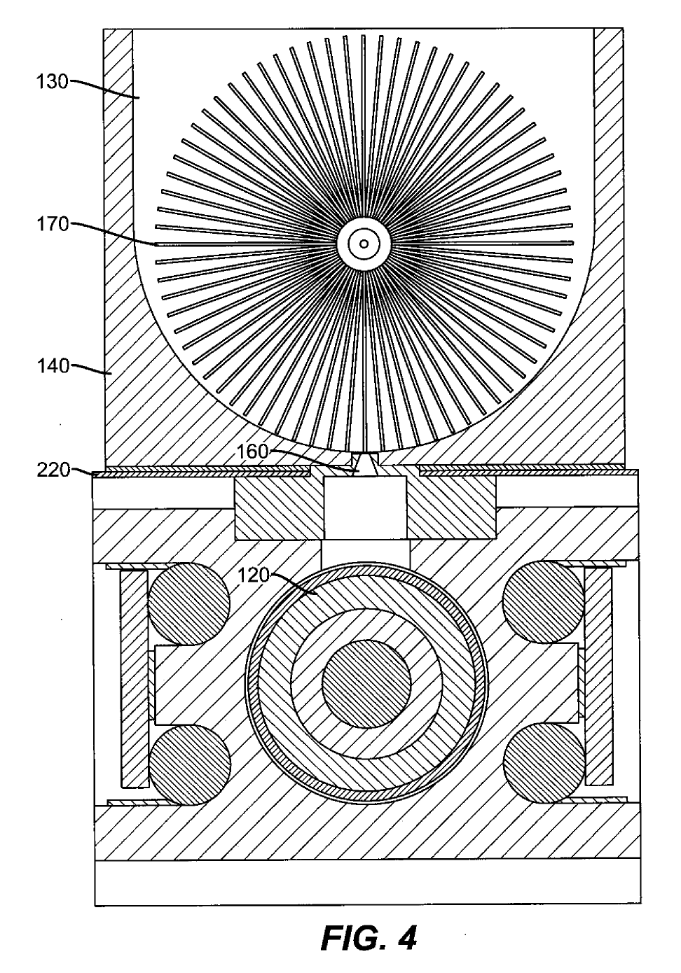

Turning now to FIG. 4, there is shown a cross-sectional view of a portion of the inventive apparatus of FIG. 3 in the plane of opening 160 in housing 140 and the middle of rotatable wire wheel brush 170. Wire wheel brush 170 is aligned with opening 160. Flash evaporator 120 and cylindrical foam element 150 (which can be seen more clearly in FIG. 3) are desirably reticulated vitreous carbon as described by Long et al. in commonly assigned U.S. patent application Ser. No. 11/834,039, or reticulated nickel, tungsten, titanium, molybdenum or tantalum. Such reticulated material allows particulate material that falls into vaporizing chamber 210 to be largely trapped by flash evaporator 120 and heated rapidly to vaporize it. Some particulate material can rebound from, or be ejected by, flash evaporator 120, or can simply fall from it. Cylindrical foam element 150 acts as a secondary heating element to rapidly vaporize these particles. Flash evaporator 120 and cylindrical foam element 150 can be heated directly. Alternatively, evaporator enclosure 210, within which flash evaporator 120 and cylindrical foam element 150 are located, can be heated. Reservoir 130 and housing 140 can be actively cooled. Wire wheel brush 170, and particulate material entrained in it, can be maintained by the active cooling at a temperature below the desired vaporization temperature of the particulate material. Only a small portion of particulate material—the portion that reaches and falls through second opening 160—is heated to the rate-dependent vaporization temperature, while the bulk of the material is kept well below the vaporization temperature. Wire wheel brush 170 can keep the particulate material well entrained in its tines so that when it is stopped, the particulate material is largely prevented from entering opening 160. Therefore, it is possible to rapidly stop and start the vaporization by stopping and starting the rotation of wire wheel brush 170. The vaporization can be stopped when a substrate surface is not being coated so as to conserve organic material and minimize contamination of any associated apparatus, such as the walls of vaporizing chamber 210. This is an advantage over many prior art devices that use temperature to control the rate of vaporization, and which do not permit rapid stopping and starting, or rapid rate of vaporization change.

The residence time of the material at elevated temperature, that is, at the rate-dependent vaporization temperature, is orders of magnitude less than many prior art devices and methods (seconds vs. hours or days in the prior art), which permits heating material to higher temperatures than in the prior art. Thus, the current device and method can achieve substantially higher vaporization rates, without causing appreciable degradation of the organic material components because the product of exposure time and temperature is substantially lower than in prior art devices.

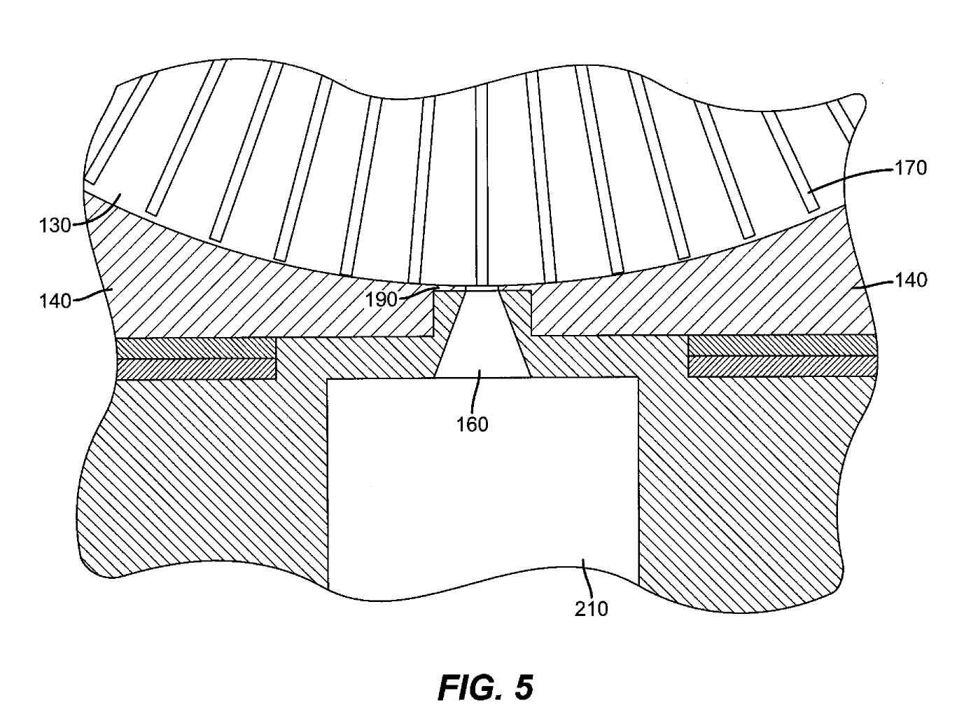

Turning now to FIG. 5, there is shown a portion of the apparatus of FIG. 4 in greater detail. Opening 160 is at the bottom of reservoir 130 for the transfer of particulate material into vaporizing chamber 210, which is heated. Heat transfer from vaporizing chamber 210 to the particulate material in reservoir 130 can heat the particulate material, potentially leading to material degradation, melting, or vaporization. To prevent such heat transfer, divider 190 is a part of housing 140, which is cooled, and prevents heating of particulate material in the vicinity of opening 160 in reservoir 130.

Opening 160 has an increasing cross sectional area as it penetrates into vaporizing chamber 210 to encourage the material dislodged from the wire wheel brush 170 to fall into vaporizing chamber 210 without clinging to the walls of the opening. The light contact between rotatable wire wheel brush 170 and opening 160 of both housing 140 and vaporizing chamber 210 creates a positive displacement metering configuration that forcefully releases the material out of the reservoir and into vaporizing chamber 210 without reliance on gravity. The rate of particulate material transfer into vaporizing chamber 210 can be controlled by controlling the rotation rate of wire wheel brush 170, which entrains a metered portion of particulate material per unit of angular displacement.

Experimentally, it has been observed that fine particulate material is considerably more difficult to meter in a partial vacuum below half an atmosphere. The particulate material agglomerates as residual air molecules are removed, and behaves more like a solid than a pourable powder. Despite this tendency, the material feeding and vaporizing device of this disclosure has proven capable of dispensing materials with a particle size dispersion below 50 microns as well as materials prepared to have particle size dispersions between 50 and 100 microns and between 100 and 200 microns.

Managing condensation in powder-fed vaporization systems is extremely important, as this is a primary cause of material feed problems and material degradation or fractionalization. Opening 160 to vaporizing chamber 210 is made sufficiently large to permit the material to pass into the vaporizing chamber, but at less than 1 mm diameter, the opening is purposely made to have a low conductance to the backflow of vapor. All of the points of condensation in this device are self limiting and confined to very small areas. After an initial vaporization period, the material feed rate will stabilize.

This configuration substantially increases the attainable temperature gradient in the particulate material between the temperature of wire wheel brush 170 and that of vaporizing chamber 210. This gradient prevents leaching of more volatile constituents from bulk volumes of mixed-component materials and enables a single source to co-deposit multiple-particulate materials.

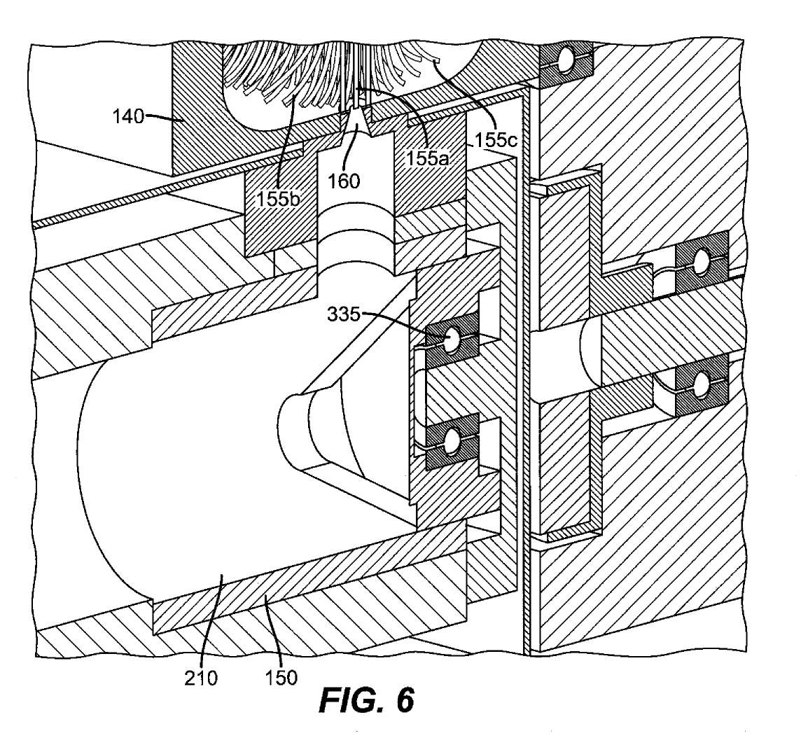

Turning now to FIG. 6, there is shown a three-dimensional cross-sectional view of a portion of the apparatus of FIG. 3. Wire wheel brush 170 comprises multiple tines. Only those tines aligned with opening 160, e.g. tines 155a, will actually sweep particulate material into opening 160. Tines that are displaced to one side or the other, e.g. tines 155b and 155c, serve to scrape off particulate material that may be adhering to the inner walls of housing 140, and to fluidize the particulate material for improved flow into opening 160.

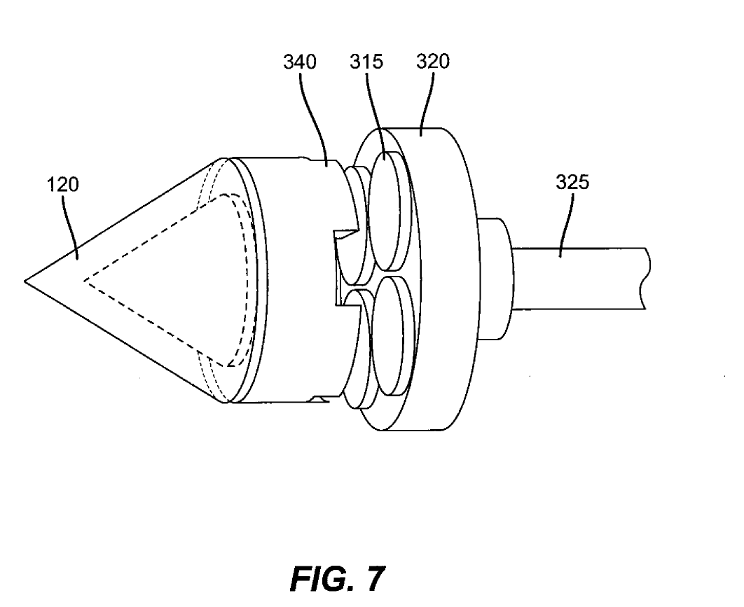

Turning now to FIG. 7, and referring also to FIG. 6, there is shown a three-dimensional view of the rotatable flash evaporator of FIG. 3 showing a magnetic coupling 320 for rotating rotatable flash evaporator 120 inside of vaporizing chamber 210 without physical contact between the cold magnetic drive coupling and the hot vaporization element or breach of the vapor integrity of vaporizing chamber 210. This arrangement has been described by Long et al. in U.S. patent application. Ser. No. 12/271,211, the contents of which are incorporated by reference. The coupling includes several magnets 315; attached to a rotating drive shaft 325 via magnetic coupling 320, that cooperate with drive lugs 340 attached to rotatable flash evaporator 120. The flash evaporator and its attached drive lugs are supported on a ceramic bearing (bearing 335 in FIG. 6). The non-contact, magnetic drive between hot rotatable flash evaporator 120 and cold rotary drive shaft 325 prevents heat flow between them, thereby permitting rotatable flash evaporator 120 to be heated by radiation from vaporizing chamber 210 without requiring the use of additional heating elements that rotate with the flash evaporator or the complication of slip rings to transfer power to the additional heating elements. Magnetic coupling 320 further eliminates the need to seal around the rotary drive connection to rotatable flash evaporator 120. The magnetic coupling is effective at temperatures in excess of 600° C. because the magnets 315 are shielded and remain cold while the low carbon steel drive lugs 340 retain their low magnetic reluctance at temperatures approaching 700° C.

In practice, vaporization apparatus 100 is used as follows. Particulate material is received in reservoir 130, which is formed in housing 140 as described above. Rotatable wire wheel brush 170 as described above is rotated in reservoir 130, whereby wire wheel brush 170 entrains particulate material from reservoir 130 and discharges it through opening 160 to deliver metered amounts of particulate material to vaporizing chamber 210 and flash evaporator 120, wherein the metered particulate material is flash evaporated.

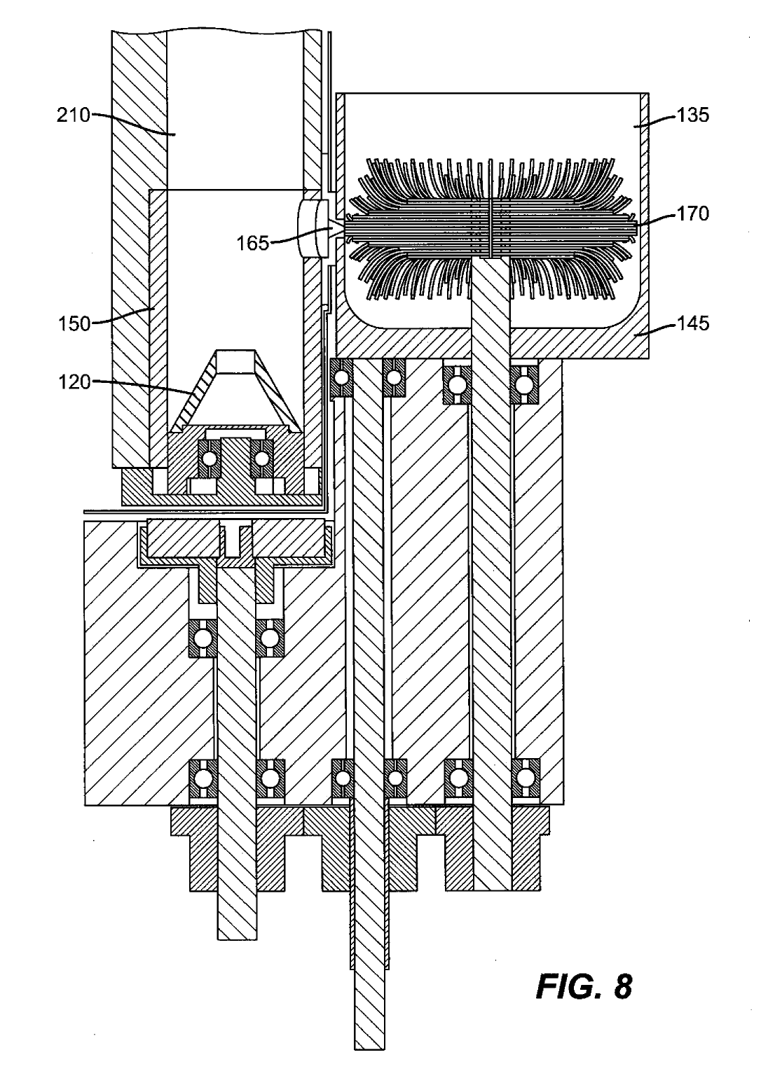

The material feeding and vaporizing device of this disclosure is effective at transporting particulate material when the wire brush wheel axis is horizontal as shown in FIGS. 3-6, but it can also be used in other orientations. The particulate material is forced into the wire brush wheel as it rotates and is retained therein sufficiently well to make its operation gravity-independent for many materials. Turning now to FIG. 8, there is shown an embodiment wherein the axis of the wire brush wheel 170 is oriented vertically. Wire wheel brush 170, flash evaporator 120, and vaporizing chamber 210 can be the same as described above but turned 90 degrees. Reservoir 135 in housing 145 has been modified to accommodate the change in orientation. Wire wheel brush 170 cooperates with reservoir 135 as described above to fluidize particulate material and to force material through opening 165 into vaporizing chamber 210 where it will fall onto flash evaporator 120 and be flash evaporated. These characteristics are significant in enabling the controlled vaporization of mixed component organic materials, and organic materials that liquefy before vaporizing.

The invention has been described in detail with particular reference to certain preferred embodiments thereof, but it will be understood that variations and modifications can be effected within the spirit and scope of the invention.

### PARTS LIST

5 auger screw
7 barrel
8 auger structure
9 thread-free portion
10 vaporization device
11 source
12 source
13 source
14 vapor plume
15 substrate
100 vaporizing apparatus
120 flash evaporator
125 shaft
130 reservoir
135 reservoir
140 housing
145 housing
150 cylindrical foam element
155a tines
155b tines
155c tines
160 opening
165 opening
170 wire wheel brush
175 shaft
180 shaft
190 divider
210 vaporizing chamber
220 insulator
315 magnet
320 magnetic coupling
325 drive shaft
335 bearing
340 drive lugs

1. An apparatus for vaporizing a particulate material, comprising:
a. a metering apparatus including:
i. a reservoir for receiving particulate material;
ii. the reservoir having an opening for discharging the particulate material into a vaporizing chamber;
iii. a rotatable wire wheel brush disposed in the reservoir;
iv. wherein the dimensions of the reservoir and the wire wheel brush are selected so that the wire wheel brush cooperates with the interior walls of the reservoir to fluidize the particulate material and wherein a metered portion of the particulate material is entrained in the tines of the wire wheel brush and subsequently forcefully released into the reservoir opening; and
b. a flash evaporator that receives and vaporizes the metered material.

2. The vaporizing apparatus of claim 1 wherein the flash evaporator is rotatable.

3. The vaporizing apparatus of claim 2 wherein the flash evaporator is rotated via a magnetic coupling.

4. The vaporizing apparatus of claim 1 wherein the flash evaporator is within a vaporizing chamber.

5. The vaporizing apparatus of claim 4 wherein the vaporizing chamber further includes a cylindrical foam element as a secondary heating element.
